(19) United States
(12) Patent Application Publication
(10) Pub. No.: US 2024/0266429 A1
(43) Pub. Date: Aug. 8, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Takahiro YAMADA, Tokyo (JP); Marika NAKAMURA, Tokyo (JP); Masanao ITO, Tokyo (JP); Yuki TAKIGUCHI, Tokyo (JP)

(73) Assignee: Mitsubishi Electric Corporation, Tokyo (JP)

(21) Appl. No.: 18/567,796

(22) PCT Filed: Jun. 14, 2021
(86) PCT No.: PCT/JP2021/022442

§ 371 Date: Dec. 7, 2023

(51) Int. Cl. H01L 29/778; H01L 29/20; H01L 29/423; H01L 29/66

(52) U.S. Cl. CPC H01L 29/7787; H01L 29/2003; H01L 29/42316; H01L 29/66462

(57) ABSTRACT

A semiconductor device includes a first nitride semiconductor layer and a second nitride semiconductor layer provided above the first nitride semiconductor layer and forming a two-dimensional electron gas between the first nitride semiconductor layer and the second nitride semiconductor layer. Above the second nitride semiconductor layer, a source electrode and a drain electrode electrically connected to the two-dimensional electron gas, and a gate electrode arranged between the source electrode and the drain electrode are provided. Between the gate electrode and the source electrode, a first oxide layer and a second oxide layer provided above the first oxide layer are formed.

### TECHNICAL FIELD

The present disclosure relates to a semiconductor device using a nitride semiconductor.

### BACKGROUND ART

A known semiconductor device fabricated using a nitride semiconductor includes a field effect transistor and a high electron mobility transistor (HEMT) and the like (for example, Patent Documents 1 and 2 below). Notably, an HEMT comprises two heterojunction nitride semiconductors with different bandgaps, at which junction interface, a high-concentration two-dimensional electron gas (2DEG) is formed. Electron mobility in 2DEG is extremely high, and the HEMT achieves low on-resistance as a lateral semiconductor device by using 2DEG as an electrically conductive layer. A nitride semiconductor has a wide bandgap, a high dielectric breakdown electric field, and a high electron saturation velocity. Therefore, a HEMT manufactured using a nitride semiconductor (hereinafter referred to as a “nitride semiconductor HEMT”) can solve the problem of the trade-off between breakdown voltage and on-resistance, and is superior to a conventional semiconductor device manufactured with silicon (Si) in operability at high output and high frequency; therefore, used for power amplifiers and the like in a wireless communication system.

### PRIOR ART DOCUMENTS

### Patent Document(s)

[Patent Document 1] Japanese Patent Application Laid-Open No. 2018-117114
[Patent Document 2] Japanese Patent Application Laid-Open No. 2019-50232

### SUMMARY

### Problem to be Solved by the Invention

To meet the increasing demand for high capacity and high-speed information communication driven by the rapid development of mobile communication tools in recent years, the enhancement of semiconductor device performance is essential. In order for the operations of the nitride semiconductor HEMT to further raise the output power and frequency, shortening of the gate length is crucial. However, with the gate length being shortened, a phenomenon called the source starvation effect which occurs due to insufficient 2DEG density on the source electrode side when switching from the off state to the on state, which raises a concern that the less-than-expected drain current value for the applied voltage is obtained.

The present disclosure has been made to solve the problems described above, and an object thereof is to provide a nitride semiconductor device capable of suppressing the source starvation effect.

### Means to Solve the Problem

According to the present disclosure, a semiconductor device includes a first nitride semiconductor layer, a second nitride semiconductor layer provided above the first nitride semiconductor layer and forming a two-dimensional electron gas between the first nitride semiconductor layer and thereof, a source electrode provided above the second nitride semiconductor layer and electrically connected to the two-dimensional electron gas, a drain electrode provided above the second nitride semiconductor layer and electrically connected to the two-dimensional electron gas, a gate electrode provided above the second nitride semiconductor layer and arranged between the source electrode and the drain electrode, a protective film provided above the second nitride semiconductor layer and arranged between the gate electrode and the drain electrode, a first oxide layer provided above the second nitride semiconductor layer and arranged between the gate electrode and the source electrode, and a second oxide layer provided above the first oxide layer.

### Effects of the Invention

According to the semiconductor device of the present disclosure, the source starvation effect can be suppressed.

The objects, features, aspects, and advantages of the present disclosure will become more apparent from the following detailed description and the accompanying drawings.

### BRIEF DESCRIPTION OF DRAWINGS

FIG. 1 A schematic cross-sectional view illustrating a configuration of a semiconductor device according to Embodiment 1.

FIG. 2 A schematic cross-sectional view illustrating Modification of a semiconductor device according to Embodiment 1.

FIG. 3 A schematic diagram illustrating electric dipoles and the direction of dipole moment formed in a laminated structure of a first oxide layer and a second oxide layer.

FIG. 4 A schematic cross-sectional view illustrating a configuration of a semiconductor device according to Embodiment 2.

FIG. 5 A schematic diagram illustrating electric dipoles and the direction of dipole moment formed in a laminated structure of first to fifth oxide layers.

FIG. 6 A schematic cross-sectional view illustrating a semiconductor device according to Embodiment 3.

### DESCRIPTION OF EMBODIMENT(S)

Hereinafter, a nitride semiconductor device according to Embodiments of the technique of the present disclosure will be described with reference to the drawings. In the drawings, components that are the same or similar to each other are denoted by the same reference numerals, and redundant description may be omitted. Also, the terms “upper” and “lower” in the description indicate the relative positional relationship of the constituent components, and are not necessarily based on the direction of gravity.

The term “nitride semiconductor” as used the present specification is a generic term for semiconductors comprising gallium nitride (GaN), aluminum nitride (AlN), indium nitride (InN), or intermediate compositions thereof.

### Embodiment 1

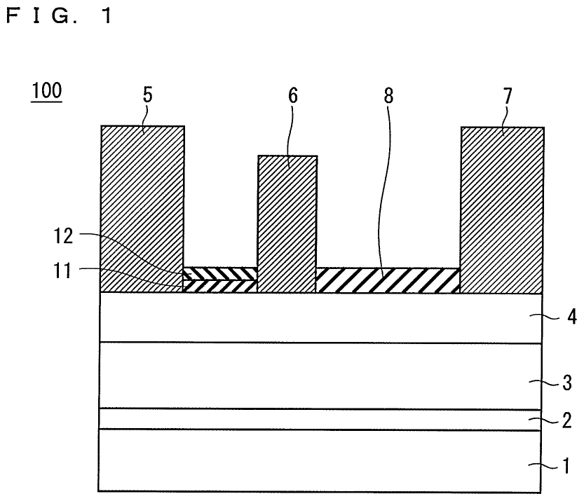

FIG. 1 is a schematic cross-sectional view illustrating a configuration of a semiconductor device 100 according to Embodiment 1. The semiconductor device 100 is a nitride semiconductor HEMT. As illustrated in FIG. 1, the semiconductor device 100 includes a substrate 1, a buffer layer 2, a first nitride semiconductor layer 3, a second nitride semiconductor layer 4, a source electrode 5, a gate electrode 6, a drain electrode 7, a protective film 8, a first oxide layer 11, and a second oxide layer 12.

The substrate 1 is composed of silicon carbide (SiC), for example. In addition to silicon carbide, silicon, gallium nitride, sapphire (aluminum oxide (Al₂O₃)), and the like are also applicable to the material of the substrate 1.

The buffer layer 2 has a function to relax lattice strain due to lattice mismatch between the substrate 1 and the first nitride semiconductor layer 3. The buffer layer 2 is composed of aluminum nitride, for example. In addition to aluminum nitride, aluminum gallium nitride (Al_{X}G_{a1-X}N(0<X<1)) or the like may be applicable to the material of the buffer layer 2. When the buffer layer 2 is composed of a material having a large bandgap, the effect of improving the breakdown voltage of the semiconductor device can be obtained along with the effect of relaxing the lattice distortion.

The first nitride semiconductor layer 3 is provided above the buffer layer 2. The first nitride semiconductor layer 3 is also referred to as a channel layer (electron transit layer). The channel layer is composed of undoped GaN, for example. The thickness of the channel layer is, for example, 0.1 μm or more and 10 μm or less.

Also, the channel layer may have a laminated structure containing, for example, one or both of iron (Fe) and carbon (C) as additive elements. For example, a channel layer having a laminated structure including a layer containing a high-concentration additive element arranged on the buffer layer 2 side and a layer containing a low-concentration additive element arranged thereabove may be used. In terms of the concentration ranges of the additive elements in the buffer layer, it is preferable that the iron concentration is 1×10¹⁵ cm⁻³ or more and 1×10¹⁹ cm⁻³ or less, and the carbon concentration is 1×10¹⁶ cm⁻³ or more and 1×10¹⁹ cm⁻³ or less. The additive elements form trapped charges in the channel layer, and the effect of suppressing leakage current from flowing through the channel layer.

The second nitride semiconductor layer 4 is provided above the first nitride semiconductor layer 3 and forms a two-dimensional electron gas (2DEG) between the first nitride semiconductor layer 3 and thereof. The second nitride semiconductor layer 4 is also referred to as a barrier layer (electron supply layer). The barrier layer is composed of, for example, aluminum gallium nitride (Al_{Y}G_{a1-Y}N(0<Y<1)). For example, a 20 nm thick layer of Al_{0.2}Ga_{0.8}N is applicable as the barrier layer. The bandgap of the barrier layer is greater than that of the channel layer, and a high-concentration 2DEG is formed even when undoped due to polarization charges generated by piezoelectric polarization and spontaneous polarization at the heterojunction interface between the channel layer and the barrier layer. The 2DEG is used as an electrically conductive layer of a nitride semiconductor HEMT.

The source electrode 5, the gate electrode 6, and the drain electrode 7 are provided above the second nitride semiconductor layer 4 in such a manner as to be spaced apart from each other. The source electrode 5 and the drain electrode 7 are metal electrodes, for example, and are specifically composed of a single layer or laminated structure of titanium (Ti), aluminum (Al), gold (Au), or the like. The connection between the source electrode 5 and the second nitride semiconductor layer 4 and the connection between the drain electrode 7 and the second nitride semiconductor layer 4 are desirable to be ohmic contacts, respectively. At least the regions of the second nitride semiconductor layer 4 below the source electrode 5 and the drain electrode 7 may be n-type doped in order to achieve ohmic contacts therewith. N-type doping can be performed, for example, by ion implantation of silicon. The source electrode 5 and the drain electrode 7 are electrically connected to the 2DEG through the second nitride semiconductor layer 4.

The gate electrode 6 is arranged between the source electrode 5 and the drain electrode 7. The gate electrode 6 is, for example, a metal electrode, and is specifically composed of a single layer or a laminated structure of nickel (Ni), platinum (Pt), or the like. The material of the gate electrode 6 may be p-type polysilicon doped with boron (B), n-type polysilicon doped with phosphorus (P), or the like, other than metal. The gate electrode 6 forms a Schottky junction between the second nitride semiconductor layer 4 and thereof.

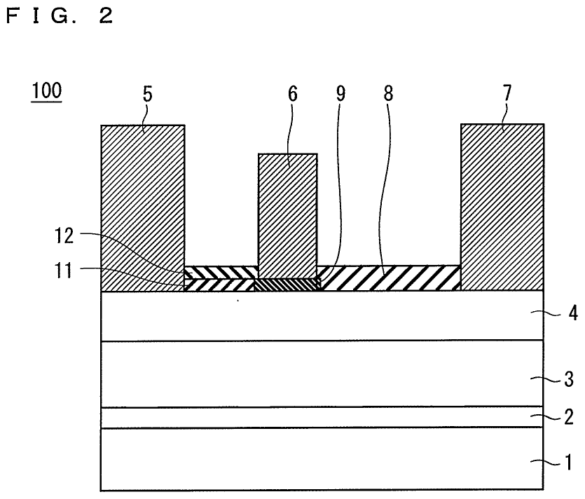

However, the junction between the gate electrode 6 and the second nitride semiconductor layer 4 does not necessarily have to be a Schottky junction and, as illustrated in FIG. 2, the metal-insulator-semiconductor (MIS) structure may be adopted to the gate portion in which a gate insulating film 9 is interposed between the gate electrode 6 and the second nitride semiconductor layer 4, for example. One of the problems with devices with a shortened gate length is the increase in gate leakage current that occurs when a forward gate voltage is applied, however, by adopting the MIS structure for the gate portion, the effect of reducing the gate leakage current can be expected. As the material of the gate insulating film 9, it is preferable to use a material with a wide bandgap such as silicon oxide (SiO₂), aluminum oxide (Al₂O₃), hafnium oxide (HfO₂) or materials with a high dielectric constant. The gate insulating film 9 is composed of a single layer or a laminated structure thereof. The gate insulating film 9 may be either amorphous or crystalline.

The protective film 8 is provided above the second nitride semiconductor layer 4 and arranged between the gate electrode 6 and the drain electrode 7. The protective film 8 is, for example, an insulating film. Also, the protective film 8 is amorphous, for example. The substrate 8 is composed of silicon nitride (SiN), for example. Aside from silicon nitride, for example, silicon oxide, silicon oxynitride (SiON), aluminum oxide, or the like can be adopted as the material of the protective film 8.

The protective film 8 has the effect of reducing deep-level defects in the energy levels present on the surface of the second nitride semiconductor layer 4, and this has the effect of suppressing the current collapse phenomenon that occurs when the transistor is driven. Meanwhile, the protective film 8 causes new interface defects between the second nitride semiconductor layer 4 and thereof. Although interface defects have a lower energy level than that of surface defects, they are considered to be a cause for the current collapse phenomenon, therefore, when forming the protective film 8, it is desirable to select a material and a film formation method that are less likely to cause interface defects between the second nitride semiconductor layer 4 and thereof.

The first oxide layer 11 is provided above the second nitride semiconductor layer 4 and arranged between the gate electrode 6 and the source electrode 5. The first oxide layer 11 is composed of silicon oxide, for example. Aside from silicon oxide, germanium oxide (GeO₂) is applicable as the material of the first oxide layer 11, for example. Similar to the protective film 8, the first oxide layer 11 reduces the density of deep-level defects present on the surface of the nitride semiconductor layer 4, and has the effect of suppressing the current collapse phenomenon. Further, the first oxide layer 11 contains nitrogen, and the nitrogen content of the first oxide layer 11 is 30% or less. The first oxide layer 11 containing nitrogen allows to obtain an effect of reducing contamination of impurities into the first oxide layer 11 from the outside. The first oxide layer 11 is amorphous, for example. The thickness of the first oxide layer 11 is, for example, 3 nm or more and 20 nm or less.

The second oxide layer 12 is provided above the first oxide layer 11 and is in contact with the first oxide layer 11. Similar to the first oxide layer 11, the second oxide layer 12 is arranged between the gate electrode 6 and the source electrode 5. The second oxide layer 12 is composed of aluminum oxide, for example. Aside from aluminum oxide, for example, an oxide composed of at least one element selected from titanium (Ti), tantalum (Ta), hafnium (Hf), magnesium (Mg), zirconium (Zr), and scandium (Sc) can also be applied as a material for the second oxide layer 12. The oxygen area density of the second oxide layer 12 is higher than the oxygen area density of the first oxide layer 11. The second oxide layer 12 is amorphous, for example. The thickness of the second oxide layer 12 is, for example, 1 nm or more and 10 nm or less.

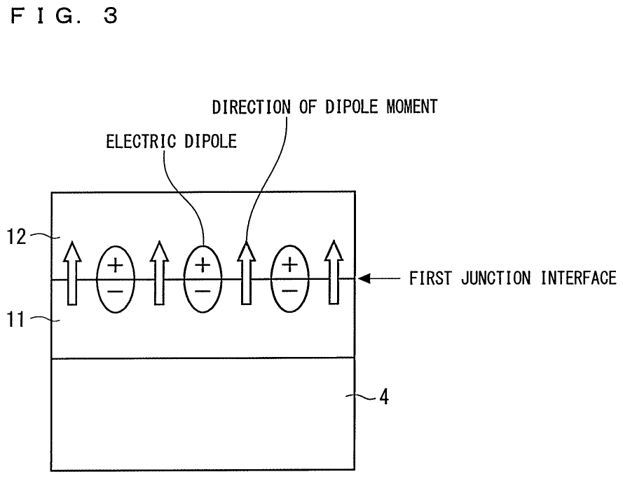

Here, the junction interface between the first oxide layer 11 and the second oxide layer 12 is defined as “first junction interface”. The second oxide layer 12 is configured such that the oxygen area density of the second oxide layer 12 is higher than the oxygen area density of the first oxide layer 11 at the first junction interface. As a result, oxygen in the second oxide layer 12 moves to the first oxide layer 11, as illustrated in FIG. 3, electric dipoles that are negatively charged on the first oxide layer 11 side and positively charged on the second oxide layer 12 side is formed at the first junction interface. Therefore, the direction of the dipole moment of the electric dipoles formed at the first junction interface directs in the direction from the first oxide layer 11 to the second oxide layer 12.

As described above, when an dipole moment of the electric dipoles formed at the first junction interface directs in the direction from the first oxide layer 11 to the second oxide layer 12, the potential of the second nitride semiconductor layer 4 located below the laminated structure of the first oxide layer 11 and the second oxide layer 12 is lowered, which increases the 2DEG density between the gate electrode 6 and the source electrode 5. Therefore, by forming the electric dipole moment at the first junction interface, the source starvation effect can be suppressed where the 2DEG density on the source electrode side is insufficient at the switching from the off-state to the on-state, which is a concern in a nitride semiconductor HEMT, especially for a short-gate nitride semiconductor HEMT. In other words, the source starvation effect can be suppressed by providing the first oxide layer 11 and the second oxide layer 12 only between the gate electrode 6 and the source electrode 5 and no oxide layer having a relationship of the oxygen area densities such as the first oxide layer 11 and the second oxide layer 12.

Here, it is preferable that the first oxide layer 11 is not a material with high ionicity. This is because when the ionicity of the material of the first oxide layer 11 is high, metal cations move simultaneously with the movement of oxygen between the second oxide layer 12 and thereof, which causes compensation of the electric charges formed at the first junction interface and no electric dipole is formed.

Next, a method of manufacturing the semiconductor device 100 according to Embodiment 1 will be described. First, above the substrate 1, each of the layers, the buffer layer 2, the first nitride semiconductor layer 3, and the second nitride semiconductor layer 4, is formed in this order by epitaxial growth. For epitaxial growth of each layer, for example, metalorganic chemical vapor deposition (MOCVD) or the like is adoptable.

Next, the protective film 8 is formed above the second nitride semiconductor layer 4. For forming the protective film 8, for example, a plasma CVD method or an atomic layer deposition (ALD) method is adoptable.

After forming the protective film 8, heat treatment is performed at a temperature below the temperature at which the protective film 8 begins to crystallize. For example, when the protective film 8 is a nitride film or an oxynitride film, the heat treatment is performed in an inert gas atmosphere. Or, when the protective film 8 is an oxide film, the heat treatment may be performed in an inert gas atmosphere containing a small amount of oxygen gas.

Subsequently, the protective film 8 other than the region between the gate electrode 6 and the drain electrode 7 is removed using techniques such as lithography and etching. As an etching method for removing the protective film 8, for example, a dry etching method, a wet etching method, or the like is adoptable. As the dry etching method, for example, an Inductively coupled plasma-Reactive ion etching (ICP-RIE) is applicable.

Next, the first oxide layer 11 and the second oxide layer 12 are formed in a region between the forming region of the source electrode 5 and the forming region of the gate electrode 6. The method of forming the first oxide layer 11 and the second oxide layer 12 may be basically the same as the method of forming the protective film 8.

After forming the first oxide layer 11 and the second oxide layer 12, heat treatment is performed in a temperature range in which the first oxide layer 11 and the second oxide layer 12 do not crystallize. The heat treatment has the effect of activating the electric dipoles formed at the first junction interface. The heat treatment is performed, for example, in an inert gas atmosphere or an inert gas atmosphere containing a small amount of oxygen gas (for example, in an atmosphere with an oxygen concentration of 0.1%).

Finally, above the second nitride semiconductor layer 4, the source electrode 5, the drain electrode 7, and the gate electrode 6 are formed, respectively. Through the above steps, the configuration of the semiconductor device 100 illustrated in FIG. 1 is obtained.

### Embodiment 2

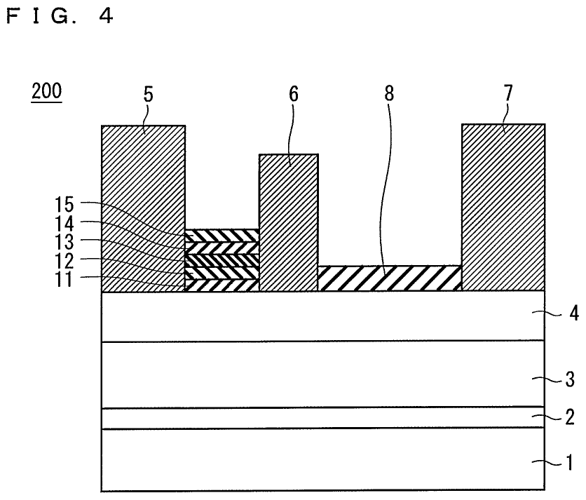

FIG. 4 is a schematic cross-sectional view illustrating a configuration of a semiconductor device 200 according to Embodiment 2. The semiconductor device 200 is a nitride semiconductor HEMT. The configuration of the semiconductor device 200 in FIG. 4 is a configuration in which, above the second oxide layer 12, a third oxide layer 13, a fourth oxide layer 14, and a fifth oxide layer 15 are added to the configuration of the semiconductor device 100 illustrated in FIG. 1. Similar to the first oxide layer 11 and the second oxide layer 12, the third oxide layer 13, the fourth oxide layer 14, and the fifth oxide layer 15 are also arranged between the gate electrode 6 and the source electrode 5.

The third oxide layer 13 is provided above the second oxide layer 12 and is in contact with the second oxide layer 12. The third oxide layer 13 is composed of yttrium oxide (Y₂O₃), for example. Aside from yttrium oxide, the oxide of at least one element from lanthanoids (La, Ce, Pr, Nd, Pm, Sm, Eu, Gd, Tb, Dy, Ho, Er, Tm, Yb, Lu) and strontium (Sr) is also applicable as material for the third oxide layer 13. The oxygen area density of the third oxide layer 13 is lower than the oxygen area density of the silicon oxide. The third oxide layer 13 is amorphous, for example. The thickness of the third oxide layer 13 is, for example, 1 nm or more and 10 nm or less.

The fourth oxide layer 14 is provided above the third oxide layer 13 and is in contact with the third oxide layer 13. The fourth oxide layer 14 is composed of silicon oxide, for example. Apart from silicon oxide, germanium oxide is applicable as the material of the fourth oxide layer 14, for example. The fourth oxide layer 14 is amorphous, for example. The thickness of the fourth oxide layer 14 is, for example, 1 nm or more and 20 nm or less.

The fifth oxide layer 15 is provided above the fourth oxide layer 14 and is in contact with the fourth oxide layer 14. The fifth oxide layer 15 is composed of aluminum oxide, for example. Aside from aluminum oxide, for example, an oxide composed of at least one element selected from titanium (Ti), tantalum (Ta), hafnium (Hf), magnesium (Mg), zirconium (Zr), and scandium (Sc) can also be applied as a material for the fifth oxide layer 15. The oxygen area density of the fifth oxide layer 15 is higher than the oxygen area density of the silicon oxide. The fifth oxide layer 15 is amorphous, for example. The thickness of the fifth oxide layer 15 is, for example, 1 nm or more and 10 nm or less.

Here, the junction interface between the second oxide layer 12 and the third oxide layer 13 is defined as “second junction interface”, the junction interface between the third oxide layer 13 and the fourth oxide layer 14 is defined as “third junction interface”, and the junction interface between the fourth oxide layer 14 and the fifth oxide layer 15 is defined as “fourth junction interface”.

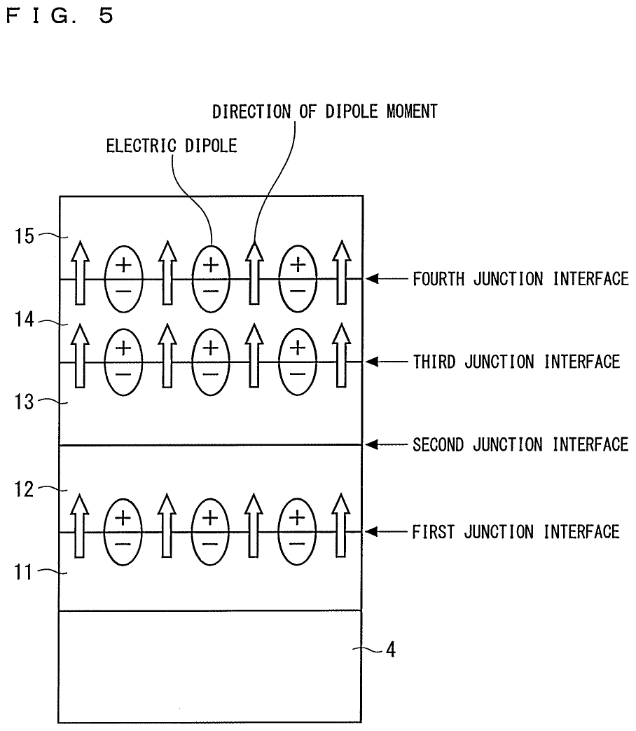

The third oxide layer 13 is configured such that the oxygen area density of the third oxide layer 12 is lower than the oxygen area density of the second oxide layer 12 at the second junction interface. With this configuration, oxygen in the second oxide layer 12 moves to the third oxide layer 13. However, since both the second oxide layer 12 and the third oxide layer 13 are materials with high ionicity, at the second junction interface, metal cations also move to compensate for the electric dipoles formed by the movement of oxygen. Therefore, as illustrated in FIG. 5, no electric dipole is formed at the second junction interface. For example, when the second oxide layer 12 is aluminum oxide and the third oxide layer 13 is yttrium oxide, the oxygen area densities of the two are significantly different, but no electric dipole is formed at the second junction interface. This has been confirmed experimentally (Reference: S. Hibino et al., “Counter Dipole Layer Formation in Multilayer High-k Gate Stacks”, Japanese Journal of Applied Physics 51, 081303 (2012)).

Meanwhile, the fourth oxide layer 14 is configured such that the oxygen area density of the fourth oxide layer 14 is higher than the oxygen area density of the third oxide layer 13 at the third junction interface. Also, the fifth oxide layer 15 is configured such that the oxygen area density of the fifth oxide layer 15 is higher than the oxygen area density of the fourth oxide layer 14 at the fourth junction interface. Therefore, electric dipoles are formed at each of the third junction interface and the fourth junction interface. The electric dipoles formed at the third junction interface are negatively charged on the third oxide layer 13 side and positively charged on the fourth oxide layer 14 side. The electric dipoles formed at the fourth junction interface are negatively charged on the fourth oxide layer 14 side and positively charged on the fifth oxide layer 15 side. Therefore, the direction of the dipole moment of the electric dipoles formed at the third junction interface and the direction of the dipole moment of the electric dipoles formed at the fourth junction interface are the same direction, and the direction of the dipole moment of the electric dipoles formed at the first junction interface is also the same direction.

Therefore, the strength of the dipole moment generated at the first oxide layer 11, the second oxide layer 12, the third oxide layer 13, the fourth oxide layer 14, and the fifth oxide layer 15 of the semiconductor device 200 according to Embodiment 2 is higher than the strength of the dipole moment generated in the laminated structure of the first oxide layer 11 and the second oxide layer 12 of the semiconductor device 100 according to Embodiment 1. Specifically, the strength of the dipole moment generated in the region between the source electrode 5 and the gate electrode 6 of the semiconductor device 200 according to Embodiment 2 is higher than the strength of the dipole moment generated in the region between the source electrode 5 and the gate electrode 6 of the semiconductor device 100 according to Embodiment 1. As a result, the 2DEG density between the gate electrode 6 and the source electrode 5 of the semiconductor device 200 according to Embodiment 2 becomes higher than that of the semiconductor device 100 of Embodiment 1, accordingly, the effect of suppressing the source starvation phenomenon of the nitride semiconductor HEMT is also enhanced more than that of Embodiment 1.

Note that the method of manufacturing the semiconductor device 200 according to Embodiment 2 is the method in which a step of forming the third oxide layer 13, the fourth oxide layer 14, and the fifth oxide layer 15 on the second oxide layer 12 is added to the method of manufacturing the semiconductor device 100 according to Embodiment 1. Then, after forming the first oxide layer 11, the second oxide layer 12, the third oxide layer 13, the fourth oxide layer 14, and the fifth oxide layer 15, the heat treatment for activating the electric dipoles is performed within a temperature range in which these oxide layers do not crystallize. The heat treatment is performed, for example, in an inert gas atmosphere or an inert gas atmosphere containing a small amount of oxygen gas (for example, in an atmosphere with an oxygen concentration of 0.1%).

### Embodiment 3

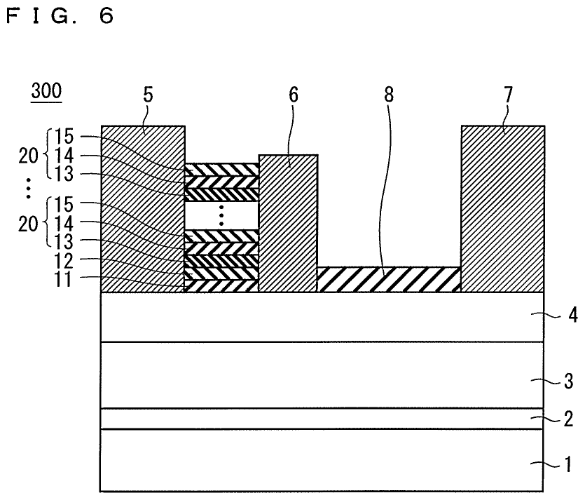

FIG. 6 is a schematic cross-sectional view illustrating a configuration of a semiconductor device 300 according to Embodiment 3. The semiconductor device 300 is a nitride semiconductor HEMT. The configuration of the semiconductor device 200 in FIG. 6 is a configuration in which, above the second oxide layer 12, laminated structures including the third oxide layer 13, the fourth oxide layer 14, and the fifth oxide layer 15 are periodically stacked are added to the configuration of the semiconductor device 200 illustrated in FIG. 4. Hereinafter, the laminated structure 20 including the third oxide layer 13, the fourth oxide layer 14, and the fifth oxide layer 15 is referred to as a “unit laminated structure”.

Each of the unit laminated structures 20 includes the second junction interface that is a junction interface between the second oxide layer 12 and the third oxide layer 13, and the third junction interface that is a junction interface between the third oxide layer 13 and the fourth oxide layer 14. Also as described in Embodiment 2, the direction of the dipole moment of the electric dipoles formed at the third junction interface and the direction of the dipole moment of the electric dipoles formed at the fourth junction interface are the same direction, and the direction of the dipole moment of the electric dipoles formed at the first junction interface is also the same direction. Therefore, the strength of the dipole moment generated in the region between the source electrode 5 and the gate electrode 6 increases as the number of stacked unit laminated structures 20 increases.

Consequently, the strength of the dipole moment generated in the region between the source electrode 5 and the gate electrode 6 of the semiconductor device 300 according to Embodiment 3 having a structure in which the unit laminated structures 20 are stacked in plural numbers is higher than the strength of the dipole moment generated in the region between the source electrode 5 and the gate electrode 6 of the semiconductor device 200 according to Embodiment 2 having only one unit laminated structure 20. As a result, the 2DEG density between the gate electrode 6 and the source electrode 5 of the semiconductor device 300 according to Embodiment 3 becomes higher than that of the semiconductor device 200 of Embodiment 2, accordingly, the effect of suppressing the source starvation phenomenon of the nitride semiconductor HEMT is also enhanced more than that of Embodiment 2.

Note that the method of manufacturing the semiconductor device 300 according to Embodiment 3 is the method in which a step of forming the third oxide layer 13, the fourth oxide layer 14, and the fifth oxide layer 15 (that is, a step of forming the unit laminated structure 20) is repeated in plural numbers is added to the method of manufacturing the semiconductor device 100 according to Embodiment 2. Then, after forming the first oxide layer 11 and the second oxide layer 12, and the plurality of unit laminated structures 20, the heat treatment for activating the electric dipoles is performed within a temperature range in which these oxide layers do not crystallize. The heat treatment is performed, for example, in an inert gas atmosphere or an inert gas atmosphere containing a small amount of oxygen gas (for example, in an atmosphere with an oxygen concentration of 0.1%).

It should be noted that Embodiments can be arbitrarily combined and can be appropriately modified or omitted.

While the forgoing description is in all aspects illustrative and not restrictive, it is therefore understood that numerous undescribed modifications and variations can be devised.

### EXPLANATION OF REFERENCE SIGNS

1 substrate, 2 buffer layer, 3 first nitride semiconductor layer, 4 second nitride semiconductor layer, 5 source electrode, 6 gate electrode, 7 drain electrode, 8 protective film, 9 gate insulating film, 11 first oxide layer, 12 second oxide layer, 13 third oxide layer, 14 fourth oxide layer, 15 fifth oxide layer, 20 unit laminated structure, 100, 200, 300 semiconductor device.

1. A semiconductor device comprising:
a first nitride semiconductor layer;
a second nitride semiconductor layer provided above the first nitride semiconductor layer and forming a two-dimensional electron gas between the first nitride semiconductor layer and thereof;
a source electrode provided above the second nitride semiconductor layer and electrically connected to the two-dimensional electron gas;
a drain electrode provided above the second nitride semiconductor layer and electrically connected to the two-dimensional electron gas;
a gate electrode provided above the second nitride semiconductor layer and arranged between the source electrode and the drain electrode;
a protective film provided above the second nitride semiconductor layer and arranged between the gate electrode and the drain electrode;
a first oxide layer provided above the second nitride semiconductor layer and arranged only between the gate electrode and the source electrode; and
a second oxide layer provided above the first oxide layer, wherein,
at a junction interface between the first oxide layer and the second oxide layer, an oxygen area density of the first oxide layer is lower than an oxygen area density of the second oxide layer.

2. (canceled)

3. The semiconductor device according to claim 1, wherein
the first oxide layer and the second oxide layer are both amorphous.

4. The semiconductor device according to claim 1, wherein
the first oxide layer contains nitrogen.

5. The semiconductor device according to claim 1, further comprising:
a third oxide layer provided above the second oxide layer;
a fourth oxide layer provided above the third oxide layer; and
a fifth oxide layer provided above the fourth oxide layer.

6. The semiconductor device according to claim 5, wherein,
at a junction interface between the second oxide layer and the third oxide layer, an oxygen area density of the second oxide layer is higher than an oxygen area density of the third oxide layer,
at a junction interface between the third oxide layer and the fourth oxide layer, an oxygen area density of the third oxide layer is lower than an oxygen area density of the fourth oxide layer, and
at a junction interface between the fourth oxide layer and the fifth oxide layer, an oxygen area density of the fourth oxide layer is lower than an oxygen area density of the fifth oxide layer.

7. The semiconductor device according to claim 5, wherein
the third oxide layer, the fourth oxide layer, and the fifth oxide layer are all amorphous.

8. The semiconductor device according to claim 5, wherein
a unit laminated structure including the third oxide layer, the fourth oxide layer and the fifth oxide layer is periodically formed above the second oxide layer.

9. A method of manufacturing the semiconductor device according to claim 1, comprising:
forming the first oxide layer and the second oxide layer; and
performing a heat treatment within a temperature range in which the first oxide layer and the second oxide layer do not crystallize.

10. A method of manufacturing the semiconductor device according to claim 5, further comprising:
forming the first oxide layer, the second oxide layer, the third oxide layer, the fourth oxide layer, and the fifth oxide layer, and
performing a heat treatment within a temperature range in which the first oxide layer, the second oxide layer, the third oxide layer, the fourth oxide layer, and the fifth oxide layer do not crystallize.
